(19) United States
(12) Patent Application Publication
(10) Pub. No.: US 2016/0135292 A1
(43) Pub. Date: May 12, 2016

(54) DETACHABLE CORE SUBSTRATE AND METHOD OF MANUFACTURING CIRCUIT BOARD USING THE SAME

(71) Applicant: Samsung Electro-Mechanics Co., Ltd., Suwon-si (KR)

(72) Inventor: Jae-Seok LEE, Daejeon (KR)

(73) Assignee: SAMSUNG ELECTRO-MECHANICS CO., LTD., Suwon-si (KR)

(21) Appl. No.: 14/935,648

(22) Filed: Nov. 9, 2015

(30) Foreign Application Priority Data
Nov. 10, 2014 (KR) 10-2014-0155433

(51) Int. Cl. H05K 1/02; H05K 3/46; H05K 3/00; H05K 3/06; H05K 1/03; H05K 1/09

(52) U.S. Cl. CPC H05K 1/0298; H05K 1/0306; H05K 1/09; H05K 3/007; H05K 3/06; H05K 3/4605; H05K 2201/0355

(57) ABSTRACT

A detachable core substrate and corresponding method include a primer coated metal foil laminated on a core, an insulation layer laminated on the primer coated metal foil, and a first metal foil laminated on the insulation layer. The primer coated metal foil, the insulation layer, and the first metal foil are successively laminated on an upper surface and a lower surface of the core to be symmetrical about the core.

### CROSS-REFERENCE TO RELATED APPLICATIONS

This application claims the benefit under 35 USC 119(a) of Korean Patent Application No. 10-2014-0155433, filed with the Korean Intellectual Property Office on Nov. 10, 2014, the disclosure of which is incorporated herein by reference in its entirety.

### BACKGROUND

1. Technical Field

The following description relates to a detachable core substrate and a method of manufacturing a circuit board using the detachable core substrate.

2. Background Art

An increasing number of electronic products are being manufactured utilizing a coreless method in order to produce thinner substrates for semiconductor packages. The coreless method is a cost effective process.

A conventional printed circuit board including electronic components installed thereon is fabricated using a copper clad laminate (CCL) or prepreg as a base on which the circuit board is laminated.

Conventional substrates for IC packaging (hereinafter, packaging substrates) are fabricated by directly forming a wiring layer on a CCL (copper coated laminate) base which is made by pressing a copper foil onto a resin core layer. However, CCL or prepreg have little effect on properties of a substrate despite the great thickness they form in the substrate. This has led to studies for forming a circuit without any basic material in order to realize a very thin substrate, and such a method is referred to as a coreless method.

In the coreless method, a core layer, on which an electronic circuit is formed, is separable from the circuit board, which is the layer on which the electronic circuit is formed.

There have been many studies to develop a detachable core substrate using the coreless method.

As the circuit widths have been reduced in the printed circuit board and the electronic devices being increasingly lighter, thinner, and smaller, there is a growing demand for a reliable detachable core substrate in which a finer circuit is formed with a low coefficient of thermal expansion and low warpage.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided a substrate, including: a primer coated metal foil laminated on a core; an insulation layer laminated on the primer coated metal foil; and a first metal foil laminated on the insulation layer, wherein the primer coated metal foil, the insulation layer, and the first metal foil are successively laminated on an upper surface and a lower surface of the core to be symmetrical about the core.

The primer coated metal foil may include, in an order from each of the upper surface and the lower surface of the core to farthest from the core, a carrier film, a release layer, a second metal foil, and a primer layer.

A joint interface between the release layer and the carrier film and a joint interface between the release layer and the second metal foil may be separation interfaces, separated during fabrication of a circuit board.

The insulation layer may be made of a prepreg material, in which glass fiber or carbon fiber is impregnated in a resin.

At least one of the first metal foil and the second metal foil may be a copper foil.

The core, the primer coated metal foil, the insulation layer, and the first metal foil may be laminated in a lump.

An adhesive force at a joint interface between the primer layer and the insulation layer or between the primer layer and the second metal foil may be between about 0.05 kgf/cm2 and 0.2 kgf/cm2.

In accordance with an embodiment, there is provided a method of manufacturing a circuit board, including: preparing a substrate including a primer coated metal foil, a first insulation layer, and a first metal foil, which are successively laminated on an upper surface and a lower surface of a core to be symmetrical about the core; forming an inner circuit layer by etching the first metal foil; sequentially forming a second insulation layer, a second primer layer, and a third metal foil on the inner circuit layer and the first insulation layer; and removing the release layer from a substrate including the third metal foil.

In an order from each of the upper surface and the lower surface of the core to farthest from the core, may further include: configuring the primer coated metal foil to comprise a carrier film, a release layer, a second metal foil, and a primer layer.

The preparing of the detachable core substrate may include: successively laminating the primer coated metal foil, the first insulation layer, and the first metal foil in a lump on both surfaces of the core so that the first primer layer is interposed between the second metal foil and the first insulation layer; and compressing the lump.

The first primer layer may be provided in about 80% to 90% level of semi-cured state in the laminating of the lump.

Upon the removing of the release layer, a coreless type of circuit board may be separated from both sides of the core having the carrier film formed thereon.

At least one of the first insulation layer and the second insulation layer may be made of a prepreg material in which glass fiber or carbon fiber is impregnated in a resin.

At least one of the first metal foil, the second metal foil, and the third metal foil may be a copper foil.

In accordance with an embodiment, there is provided a substrate, including: a primer coated metal foil including a carrier film, a release layer, a second metal foil and a primer layer laminated on a core; an insulation layer laminated on the primer coated metal foil; and a first metal foil laminated on the insulation layer, wherein the primer coated metal foil, the insulation layer, and the first metal foil are laminated on at least one of an upper surface and a lower surface of the core.

The primer coated metal foil, the insulation layer and the first metal foil may be successively laminated in a lump on the at least one of an upper surface and a lower surface of the core so that the primer coated metal foil, the insulation layer, and the first metal foil are symmetrical about the core.

The primer layer may be interposed between the first metal foil and the insulation layer to tightly adhere the first metal foil and the insulation layer.

The release layer may be formed on the carrier film and is configured with a release force sufficient to enable release of the core.

Other features and aspects will be apparent from the following detailed description, the drawings, and the claims.

### BRIEF DESCRIPTION OF DRAWINGS

FIG. 1 is a cross-sectional view showing a detachable core substrate, in accordance with an embodiment.

FIG. 2 is an exploded view of the detachable core substrate shown in FIG. 1.

FIG. 3 illustrates a preparation of the detachable core substrate shown in FIG. 1.

FIG. 4 illustrates a formation of an inner circuit layer of the detachable core substrate shown in FIG. 1.

FIG. 5 an additional formation of an insulation layer, a primer layer, and a metal foil of the detachable core substrate shown in FIG. 1.

FIG. 6 illustrates a separation of a circuit board of the detachable core substrate shown in FIG. 1.

FIG. 7 is a flow chart illustrating the processes performed in FIG. 3 through FIG. 6.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. These terms do not necessarily imply a specific order or arrangement of the elements, components, regions, layers and/or sections. Thus, a first element, component, region, layer or section discussed below could be termed a second element, component, region, layer or section without departing from the embodiments described.

Hereinafter, a detachable core substrate and a method of manufacturing a circuit board using the detachable core substrate, in accordance with an embodiment, will be described with reference to the accompanying drawings.

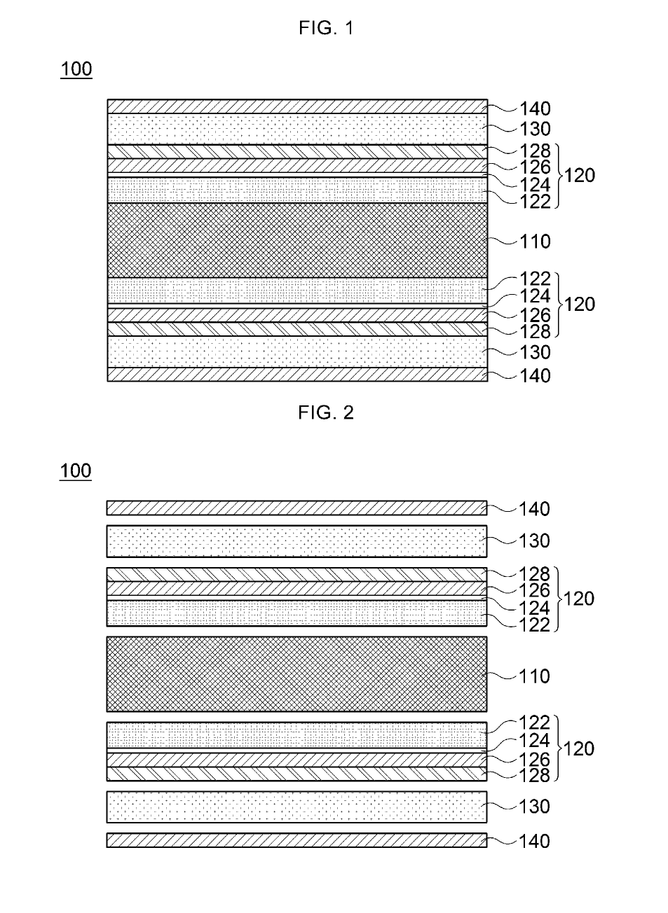

FIG. 1 is a cross-sectional view showing a detachable core substrate, in accordance with an embodiment, and FIG. 2 is an exploded view of the detachable core substrate shown in FIG. 1.

Referring to FIG. 1, a detachable core substrate 100, in accordance with an embodiment, includes a core 110, primer coated metal foils 120 formed on either surface of the core 110, insulation layers 130 formed on the primer coated metal foils 120, and metal foils 140 formed on the insulation layers 130. In one embodiment, the primer coated metal foils 120, the insulation layer 130, and the metal foils 140 are formed on an upper surface of the core 110. In another embodiment, the primer coated metal foils 120, the insulation layer 130, and the metal foils 140 are formed on a lower surface of the core 110. In a further embodiment, the primer coated metal foils 120, the insulation layer 130, and the metal foils 140 are formed on both, the upper and the lower surfaces of the core 110.

According to the above configuration, the detachable core substrate 100 has a symmetrical structure relative to the core 110, in which the primer coated metal foils 120, the insulation layers 130 and the metal foils 140 are successively laminated in the listed sequence. However, a person of relevant skill in the art will appreciate that the order of the primer coated metal foils 120, the insulation layer 130, and the metal foils 140 may be laminated in a different sequence.

The core 110 is used as a base material to manufacture the detachable core substrate 100 and is later removed when a circuit board is manufactured.

Accordingly, the core 110 is formed of any material and may be a thermosetting or thermoplastic polymer substrate, a ceramic substrate, an organic-inorganic hybrid material resin or a glass cloth impregnated substrate. In the case where the core 110 includes polymer resin, the core 110 includes insulation resin, for example, epoxy resin, polyimide resin, ABF, BT, prepreg, etc.

In one embodiment, the primer coated metal foils 120 are formed, respectively, above and below the core 110. That is, the primer coated metal foils 120 are formed both surfaces of the core 110.

The primer coated metal foils 120 are each configured as a laminate including, in an order from the surface of the core 110 to farthest from the core 110, a carrier film 122, a release layer 124, a metal foil 126 and a primer layer 128. In one example, the primer coated metal foil 120 refers to the metal foil 126 coated with the primer layer 128.

The carrier film 122 is used as a base material when the primer coated metal foil 120 is manufactured and may be made of a polymer film including, for example, polyethyleneterephthalate (PET), polycarbonate (PC), polyethylene (PE), oriented polypropylene (OPP) or polyvinylchrolide (PVC) or a combination thereof.

The carrier film 122 is in contact with and formed on an upper surface of the core 110 and on a lower surface of the core 110.

In a detachable core substrate 100, the release layer 124 is for manufacturing a coreless type circuit board by separating and removing the core 110. The release layer 124 is formed on the carrier film 122 and is configured with a release force sufficient to enable release of the core substrate 100.

Although not restricted to a particular material, the release layer 124 may be formed of various kinds of films, for example, PET film, polyester film, PVC film and composite films of polyester-PVC, polyester-PP or polyester-PE. For instance, for an easy release, a PET film having the release force of about 10 g/in may be used.

The release layer 124 has one surface adhered to the carrier film 122 and the other surface of the release layer 124 is adhered to the metal foil 126. Accordingly, a joint interface between the release layer 124 and the carrier film 122 and a joint interface between the release layer 124 and the metal foil 126 become separation interfaces that are separated when the circuit board is fabricated.

The metal foil 126, which is used as a part of an outer circuit layer when a multilayered circuit board is fabricated, is made of a conductive material having a good electric conductivity, for example, copper foil. The metal foil 126 is formed through plating.

The primer layer 128 is interposed between the metal foil 126 and the insulation layer 130 to allow the metal foil 126 and the insulation layer 130 to be tightly adhered to each other. That is, the primer layer 128 is configured to enhance an interlayer adhesion between the metal foil 126 and the insulation layer 130.

In an example, the primer layer 128 is made of any of acrylic resin, acrylic urethane resin, epoxy resin, polyurethane resin, polyisocyanate resin, polyester resin, acrylate resin, ethylene-vinylacetate copolymer resin, polyamide resin, melamine resin, synthetic rubber resin and polyvinyl alcohol resin or a combination thereof.

The insulation layer 130 is formed on the primer layer 128 of the primer coated metal foil 120. The insulation layer 130, which is form insulation of an inner circuit layer when the circuit board is fabricated, is made of a resin material, for example, epoxy, polyimide, ABF, BT or prepreg (PPG).

Alternatively, the insulation layer 130 is made of a prepreg material in which glass fiber, such as glass cloth or fabric cloth, or carbon fiber is impregnated in a resin.

In one example, the insulation layer 130 is made of a prepreg containing a core material, such as glass cloth, in which case the circuit board has an enhanced rigidity and an improved warpage property.

The metal foil 140, which is used as a part of the inner circuit layer when the circuit board is fabricated, is made of a conductive material having a good electric conductivity, for example, copper foil.

The detachable core substrate 100, configured as described above, is formed by laminating the primer coated metal foils 120, the insulation layers 130 and the metal foils 140, successively, in a lump on either surface or both surfaces of the core 110 in such a way that the primer coated metal foils 120, the insulation layers 130 and the metal foils 140 are symmetrical about the core 110. Also, the primer layer 128 is interposed between the metal foil 126 and the insulation layer 130. The primer coated metal foils 120, the insulation layers 130 and the metal foils 140 with the core 110 are compressed under high pressure at a high temperature environment, as shown in FIG. 2.

In one example, the primer layers 128 of the detachable core substrate 100 are hardened to a C-stage state. Moreover, the adhesive force at joint interfaces between the primer layer 128 and the insulation layer 130 and between the primer layer 128 and the metal foil 126 are between about 0.05 kgf/cm2 and 0.2 kgf/cm2, in which range a stable adhesion is maintained without exfoliation of the insulation layer 130 and/or the metal foil 126.

Further, before the compressing, the primer layer 128 used in the laminating in a lump is hardened to about 80% to 90% level of semi-cured state after being coated on the metal foil 126. The primer layer 128 is hardened before compressing because if the primer layer 128 were fully hardened, it would be difficult to have the primer layer 128 adhered to the insulation layer 130.

That is, in the case where the detachable core substrate 100 is formed by lamination in a lump, an optimal adhesion is provided between the primer layer 128 and the insulation layer 130 because there is no possibility of the primer layer 128 to be fully hardened before being joined with the insulation layer 130 during the manufacture of the detachable core substrate 100.

If the harness of the primer layer 128 is less than 80% before lamination, it may not be easy to handle the primer layer 128, and if the hardness is over 90%, the adhesion with the insulation layer 130 may not be sufficient, possibly resulting in separation of the insulation layer 130 from the metal layer 126.

The detachable core substrate 100, configured as described above, has an excellent product reliability, owing to the stability of interlayer adhesion provided by the primer layer 128. The detachable core substrate 100 enables an implementation of a circuit forming method using a coreless type of semi additive process (SAP) when a circuit board is manufactured.

Moreover, because the detachable core substrate 100, in accordance with an embodiment, is formed through lamination in a lump, it is possible to improve the productivity and save the manufacturing costs through simplified manufacturing processes.

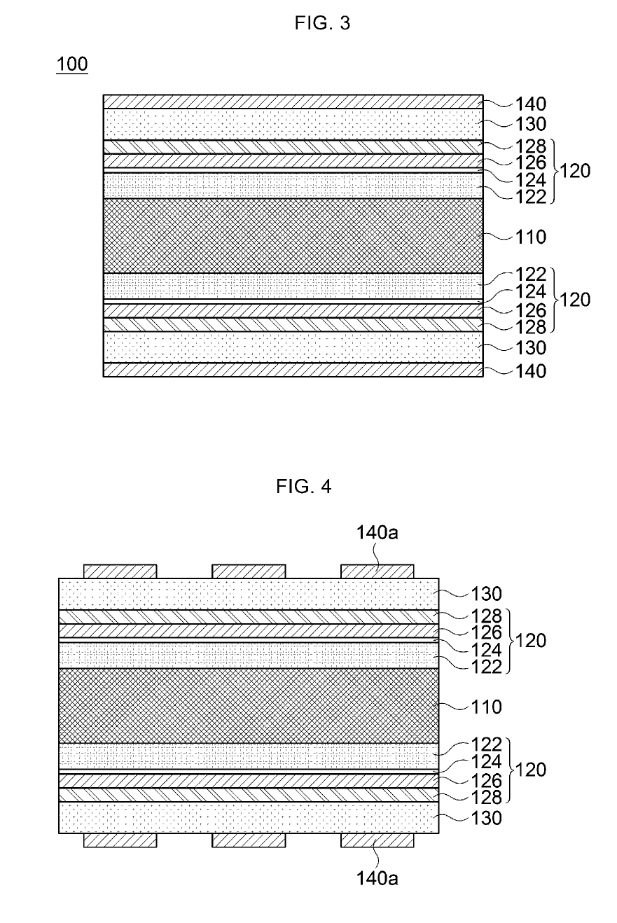

Hereinafter, a method of manufacturing a circuit board using the detachable core substrate shown FIG. 1 will be described with reference to FIG. 3 to FIG. 7.

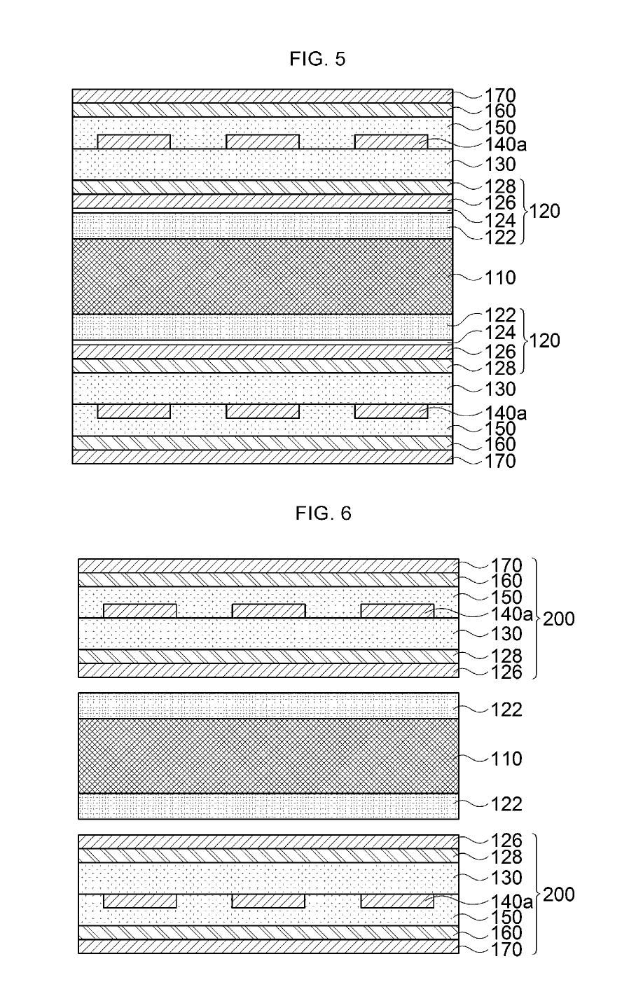

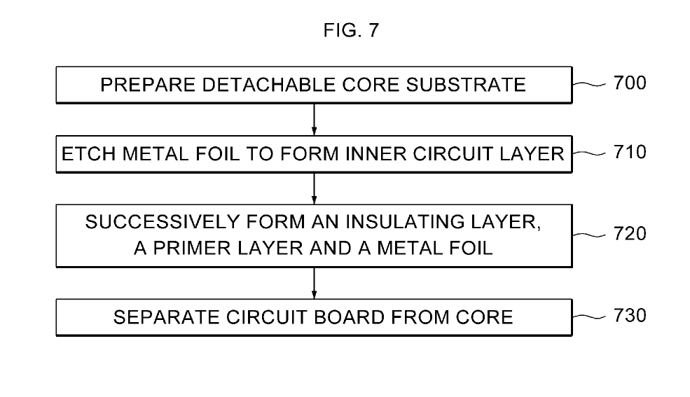

FIG. 3, FIG. 4, FIG. 5 and FIG. 6 show processes of a method of manufacturing a circuit board using the detachable core substrate shown in FIG. 1. FIG. 3 illustrates a preparation of the detachable core substrate shown in FIG. 1. FIG. 4 illustrates a formation of an inner circuit layer. FIG. 5 an additional formation of an insulation layer, a primer layer, and a metal foil. FIG. 6 illustrates a separation of a circuit board. FIG. 7 is a flow chart illustrating the processes performed in FIG. 3 through FIG. 6.

As illustrated in FIG. 3, the method of manufacturing a circuit board, in accordance with an embodiment, begins with preparing, at operation 700 of FIG. 7, the detachable core substrate 100 configured as shown in FIG. 1.

Then, as illustrated in FIG. 4 and operation 710 of FIG. 10, an inner circuit layer 140a is formed by etching the metal foil 140 (see FIG. 3) of the detachable core substrate 100. In one example, the metal foil 140 is dry etched so as to form a fine circuit pattern.

The pitch, number and other characteristics of the inner circuit layer 140a are variably adjusted according to a manner in which the circuit board is designed.

Next, as illustrated in FIG. 5 and operation 720 of FIG. 7, an insulation layer 150, a primer layer 160, and a metal foil 170 are successively formed on the inner circuit layer 140a and the insulation layer 130.

The insulation layer 150 is for insulating the inner circuit layer 140a and is made of a resin material, for example, epoxy, polyimide, ABF, BT or prepreg.

Alternatively, the insulation layer 150 is made of a prepreg material in which glass fiber, such as glass cloth or fabric cloth, or carbon fiber is impregnated in a resin.

The insulation layer 150 made of a prepreg also contains a core material, such as glass cloth, in which case the circuit board has an enhanced rigidity and an improved warpage property.

The primer layer 160 is interposed between the insulation layer 150 and the metal foil 170 to allow the insulation layer 150 and the metal foil 170 to be tightly adhered to each other. That is, the primer layer 160 is configured to enhance an interlayer adhesion between the insulation layer 150 and the metal foil 170.

The primer layer 160 is made of any of acrylic resin, acrylic urethane resin, epoxy resin, polyurethane resin, polyisocyanate resin, polyester resin, acrylate resin, ethylene-vinylacetate copolymer resin, polyamide resin, melamine resin, synthetic rubber resin and polyvinyl alcohol resin or a combination thereof.

The insulation layer 150 or the primer layer 160 is formed by processing a resin composition through, for example, casting, dip coating, roll coating, die coating, slit coating, gravure coating, spin coating, air curtaining and spraying processes.

The metal foil 170, which is used as a part of an outer circuit layer when a multilayered circuit board is fabricated, is made of a conductive material preferably having a good electric conductivity, for example, copper foil. The metal foil 170 is formed by a plating process.

Thereafter, as illustrated in FIG. 6 and operation 730 of FIG. 7, circuit boards 200, including the metal foil 126, the primer layer 128, the insulation layer 130, the inner circuit layer 140a, the insulation layer 150, the primer layer 160, and the metal foil 170, are separated from the core 110 having the carrier films 122 formed thereon, by removing the release layers 124 (see FIG. 5).

As a result, in one illustrative example, a pair of the circuit boards 200, each including the metal foil 126, the primer layer 128, the insulation layer 130, the inner circuit layer 140, the primer layer 160 and the metal foil 170, are fabricated above and below the core 110, respectively.

As the core 110 is removed, the circuit boards 200 are each manufactured in a coreless form.

Because the circuit board 200, in accordance with an embodiment includes the primer layers 128, 160, it is possible to fabricate a fine circuit pattern using a semi additive process method.

Although not illustrated in the drawings, vias and SAP circuits may be formed on the circuit board 200 to complete the manufacturing process of the circuit board.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A substrate, comprising:
a primer coated metal foil laminated on a core;
an insulation layer laminated on the primer coated metal foil; and
a first metal foil laminated on the insulation layer,
wherein the primer coated metal foil, the insulation layer, and the first metal foil are successively laminated on an upper surface and a lower surface of the core to be symmetrical about the core.

2. The substrate as recited in claim 1, wherein the primer coated metal foil comprises, in an order from each of the upper surface and the lower surface of the core to farthest from the core, a carrier film, a release layer, a second metal foil, and a primer layer.

3. The substrate as recited in claim 2, wherein a joint interface between the release layer and the carrier film and a joint interface between the release layer and the second metal foil are separation interfaces, separated during fabrication of a circuit board.

4. The substrate as recited in claim 1, wherein the insulation layer is made of a prepreg material, in which glass fiber or carbon fiber is impregnated in a resin.

5. The substrate as recited in claim 2, wherein at least one of the first metal foil and the second metal foil is a copper foil.

6. The substrate as recited in claim 1, wherein the core, the primer coated metal foil, the insulation layer, and the first metal foil are laminated in a lump.

7. The substrate as recited in claim 2, wherein an adhesive force at a joint interface between the primer layer and the insulation layer or between the primer layer and the second metal foil is between about 0.05 kgf/cm2 and 0.2 kgf/cm2.

8. A method of manufacturing a circuit board, comprising:
preparing a substrate comprising a primer coated metal foil, a first insulation layer, and a first metal foil, which are successively laminated on an upper surface and a lower surface of a core to be symmetrical about the core;
forming an inner circuit layer by etching the first metal foil;
sequentially forming a second insulation layer, a second primer layer, and a third metal foil on the inner circuit layer and the first insulation layer; and
removing the release layer from a substrate including the third metal foil.

9. The method as recited in claim 8, wherein, in an order from each of the upper surface and the lower surface of the core to farthest from the core, further comprising:
configuring the primer coated metal foil to comprise a carrier film, a release layer, a second metal foil, and a primer layer.

10. The method as recited in claim 9, wherein the preparing of the detachable core substrate comprises:
successively laminating the primer coated metal foil, the first insulation layer, and the first metal foil in a lump on both surfaces of the core so that the first primer layer is interposed between the second metal foil and the first insulation layer; and
compressing the lump.

11. The method as recited in claim 10, wherein the first primer layer is provided in about 80% to 90% level of semi-cured state in the laminating of the lump.

12. The method as set forth in claim 9, wherein, upon the removing of the release layer, a coreless type of circuit board is separated from both sides of the core having the carrier film formed thereon.

13. The method as set forth in claim 8, wherein at least one of the first insulation layer and the second insulation layer is made of a prepreg material in which glass fiber or carbon fiber is impregnated in a resin.

14. The method as set forth in claim 9, wherein at least one of the first metal foil, the second metal foil, and the third metal foil is a copper foil.

15. A substrate, comprising:
a primer coated metal foil comprising a carrier film, a release layer, a second metal foil and a primer layer laminated on a core;
an insulation layer laminated on the primer coated metal foil; and
a first metal foil laminated on the insulation layer,
wherein the primer coated metal foil, the insulation layer, and the first metal foil are laminated on at least one of an upper surface and a lower surface of the core.

16. The substrate as recited in claim 15, wherein the primer coated metal foil, the insulation layer and the first metal foil are successively laminated in a lump on the at least one of an upper surface and a lower surface of the core so that the primer coated metal foil, the insulation layer, and the first metal foil are symmetrical about the core.

17. The substrate as recited in claim 15, wherein the primer layer is interposed between the first metal foil and the insulation layer to tightly adhere the first metal foil and the insulation layer.

18. The substrate as recited in claim 15, wherein the release layer is formed on the carrier film and is configured with a release force sufficient to enable release of the core.
